(19) United States
(12) Patent Application Publication
(10) Pub. No.: US 2012/0086040 A1
(43) Pub. Date: Apr. 12, 2012

(54) LIGHT-EMITTING DIODE HAVING A WAVELENGTH CONVERSION MATERIAL LAYER, AND METHOD FOR FABRICATING SAME

(75) Inventors: Kwang-Cheol Lee, Gwangju (KR); Jae-Pil Kim, Gwangju (KR); Sang-Bin Song, Gwangju (KR); Sang-Mook Kim, Gwangju (KR)

(73) Assignee: KOREA PHOTONICS TECHNOLOGY INSTITUTE, Buk-Gu, Gwangju (KR)

(21) Appl. No.: 13/376,714

(22) PCT Filed: Jun. 10, 2010
(86) PCT No.: PCT/KR2010/003741

§ 371 Date: Dec. 7, 2011

(30) Foreign Application Priority Data
Jun. 23, 2009 (KR) 10-2009-0055755

(51) Int. Cl. H01L 33/50

(52) U.S. Cl. 257/98; 438/29; 257/E33.06

(57) ABSTRACT

Provided is a light-emitting diode having a wavelength conversion material and a method for fabricating the same. The light-emitting diode comprises: a base structure; a light-emitting diode chip arranged on the base structure; and a wavelength conversion material layer arranged on the light-emitting diode chip, such that the area adjacent the upper surface of the light-emitting diode chip is thicker than the area adjacent to the side surface of the light-emitting diode chip. In addition, the method for fabricating a light-emitting diode comprises: a step of arranging the light-emitting diode chip on the base structure; and a step of arranging a wavelength conversion material layer containing a light-transmitting photocurable material on the light-emitting diode chip, such that the area thereof adjacent to the upper surface of the light-emitting diode chip is thicker than the area thereof adjacent to the side surface of the light-emitting diode chip.

### TECHNICAL FIELD

The present invention relates to a light-emitting diode and, more particularly, to a light-emitting diode having a wavelength conversion material layer and a method for fabricating the same.

### BACKGROUND ART

A light-emitting diode (LED) is a semiconductor device that converts current into light and is mainly used as a light source of a display device. The light-emitting diode has excellent characteristics such as extremely small size, low power consumption, long life span, high response speed, etc. compared to existing light sources. Moreover, the light-emitting diode does not emit harmful electromagnetic waves such as ultraviolet rays and does not use mercury and other discharging gases, and thus is environmentally friendly.

Among them, a white light-emitting diode is advantageous for miniaturization and high efficiency and has a long life span, compared to conventional light bulbs, and thus has been extensively studied. The white light-emitting diode is typically formed in combination with a light-emitting diode light source and a wavelength conversion material such as a fluorescent material. Such a white light-emitting diode using the wavelength conversion material is typically fabricated by the following two methods. One is a method to convert energy by forming a yellow wavelength conversion material on a blue light-emitting diode chip, and the other is a method to convert energy by forming yellow, red, green, and blue wavelength conversion materials on an ultraviolet light-emitting diode chip.

When an electric field is applied to such a light-emitting diode, light is emitted from the light-emitting diode. This light excites the wavelength conversion material to emit light and this light is mixed with the light from the light-emitting diode, thereby emitting white light. Here, the amount of light emitted from the upper surface of the light-emitting diode is more predominant than that emitted from the side of the light-emitting diode.

When the wavelength conversion material is formed into a uniform thickness on the light-emitting diode, the amount of wavelength conversion material formed on the upper surface of the light-emitting diode may be smaller than the ability of light to excite the wavelength conversion material, and the amount of light for exciting the wavelength conversion material may be insufficient in the side of the light-emitting diode.

Accordingly, the color of light may be predominant in the center of light finally emitted, and the color of the wavelength conversion material may be predominant in the side of light. As a result, the light emitted from the light-emitting diode may have non-uniform color temperature distribution for each orientation angle.

### DISCLOSURE

### Technical Problem

To solve the above-described problems, a technical object of the present invention is to provide a light-emitting diode having a wavelength conversion material layer with uniform color temperature distribution for each light orientation angle, and a method for fabricating the same.

Moreover, another technical object of the present invention is to provide a light-emitting diode having a wavelength conversion material layer formed on a light-emitting diode chip with a thickness profile proportional to the amount of light emitted from the light-emitting diode chip in all directions.

The technical objects of the present invention are not limited by the above technical objects, and other technical objects that are not mentioned will be apparently understood by a person of ordinary skill in the art from the following description.

### Technical Solution

According to an aspect of the present invention to achieve the object of the present invention, there is provided a light-emitting diode having a wavelength conversion material layer. The light-emitting diode in accordance with an exemplary embodiment of the present invention comprises: a base structure; a light-emitting diode chip disposed on the base structure; and a wavelength conversion material layer formed on the light-emitting diode chip such that the area adjacent to the upper surface of the light-emitting diode chip is thicker than the area adjacent to the side of the light-emitting diode chip.

The wavelength conversion material layer may have a thickness profile proportional to the amount of light emitted from the light-emitting diode chip, and the wavelength conversion material layer may comprise a light-transmitting photocurable material and a wavelength conversion material.

The light-transmitting photocurable material may comprise one selected from the group consisting of silicone resin, epoxy resin, acrylic resin, urethane resin, photoresist, and glass.

The wavelength conversion material may have at least one wavelength range selected from the group consisting of yellow, red, green, and blue, and the wavelength conversion material may comprise a fluorescent material, a dye, or a pigment.

The base structure may be a package lead frame, a package pre-mold frame, a sub-mount substrate, and a light-emitting diode wafer.

The light-emitting diode chip may be a vertical light-emitting diode chip and may be disposed in or on the light-emitting diode wafer.

The base structure may comprise a reflective cup.

The light-emitting diode may further comprise a protective layer disposed between the light-emitting diode chip and the wavelength conversion material layer, wherein the protective layer encapsulates the light-emitting diode chip.

The protective layer may have a dome shape that covers the light-emitting diode chip or a conformal shape that covers the light-emitting diode chip and has a uniform thickness, and the protective layer may comprise glass or light-transmitting resin.

The light-emitting diode chip may be a device that emits blue light or ultraviolet light.

The light-emitting diode may further comprise a protective layer disposed on the wavelength conversion material layer, and the protective layer may comprise glass or light-transmitting resin.

According to another aspect of the present invention to achieve the object of the present invention, there is provided a method for fabricating a light-emitting diode. The method for fabricating a light-emitting diode in accordance with another exemplary embodiment of the present invention comprises the steps of: disposing a light-emitting diode chip on a base structure; and forming a wavelength conversion material layer on the light-emitting diode chip, wherein the wavelength conversion material layer comprises a light-transmitting photocurable material, wherein the wavelength conversion material layer is formed such that the area adjacent to the upper surface of the light-emitting diode chip is thicker than the area adjacent to the side of the light-emitting diode chip.

The step of forming the wavelength conversion material layer may comprise the steps of: coating a mixture containing a wavelength conversion material and a light-transmitting photocurable material on the light-emitting diode chip; curing the mixture by exposing the mixture to light emitted by applying an electric field to the light-emitting diode chip; and removing the residual uncured mixture.

The mixture may be coated by blade coating, screen coating, dip coating, dotting, spin coating, spray, or inkjet printing.

The method may further comprise the step of forming a protective layer between the base structure and the wavelength conversion material layer.

According to still another aspect of the present invention to achieve the object of the present invention, there is provided a method for fabricating a light-emitting diode. The method for fabricating a light-emitting diode in accordance with still another exemplary embodiment of the present invention comprises the steps of: forming a plurality of light-emitting diode chips on a light-emitting diode wafer divided into a plurality of cell areas; coating a mixture containing a wavelength conversion material and a light-transmitting photocurable material on the light-emitting diode chips; curing the mixture by exposing the mixture to light emitted by applying an electric field to the light-emitting diode chips; forming a wavelength conversion material layer by removing the residual uncured mixture; and cutting the light-emitting diode wafer into a plurality of light-emitting diode cells.

The cell areas of the light-emitting diode wafer may be defined by a plurality of cutting lines and a separation pattern.

The residual uncured mixture may be removed by development and the separation pattern may also be removed by development.

The method may further comprise the step of, before the step of coating the mixture containing wavelength conversion material and light-transmitting photocurable material, forming a protective layer for encapsulating the light-emitting diode chips.

### Advantageous Effects

As described above, the light-emitting diode according to the present invention comprises the wavelength conversion material layer containing the wavelength conversion material formed over the area, into which light emitted from the light-emitting area of the light-emitting diode chip can penetrate, and thus the light emitted from the light-emitting area of the light-emitting diode chip can excite the wavelength conversion material to a certain level.

As a result, since the wavelength conversion material proportional to the amount of emitted light or the intensity of emitted light passes through the path of light emitted from the light-emitting area of the light-emitting diode, the amount of light energy emitted from the wavelength conversion material and the amount of light energy emitted from the light-emitting diode are mixed in an appropriate ratio, and thus the color temperature distribution for each orientation angle can be uniform. Moreover, when the protective layer having a uniform thickness from the top of the light-emitting area of the light-emitting diode chip or from the light-emitting diode chip is disposed on the light-emitting diode chip and the wavelength conversion material layer is disposed thereon, it is possible to prevent the wavelength conversion material layer from absorbing and scattering light, thereby improving the light extraction efficiency.

Furthermore, according to an encapsulation process of a conventional method for fabricating a light-emitting diode, an encapsulating material mixed with a wavelength conversion material is deposited on the light-emitting diode by dispensing. However, according to the light-emitting diode of the present invention, it is not necessary to employ the encapsulation process using the wavelength conversion material such as a fluorescent material, and thus it is possible to overcome the failures associated with the fluorescent material such as the shift of color coordinates.

### DESCRIPTION OF DRAWINGS

FIGS. 1 to 5 are cross-sectional views showing a method for fabricating a light-emitting diode in accordance with a first exemplary embodiment of the present invention.

FIGS. 6 to 8 are cross-sectional views showing various structures of conventional light-emitting diodes.

FIGS. 9 and 10 are an image and a graph showing color temperature distribution of a conventional light-emitting diode.

FIG. 11 is a cross-sectional view showing the structure of a light-emitting diode in accordance with the present invention.

FIGS. 12 and 13 are an image and a graph showing color temperature distribution of a light-emitting diode in accordance with the present invention.

FIG. 14 is a cross-sectional view showing the structure of a light-emitting diode in accordance with a second exemplary embodiment of the present invention.

FIG. 15 is a cross-sectional view showing the structure of a light-emitting diode in accordance with a third exemplary embodiment of the present invention.

FIG. 16 is a cross-sectional view showing the structure of a light-emitting diode in accordance with a fourth exemplary embodiment of the present invention.

FIG. 17 is a cross-sectional view showing the structure of a light-emitting diode in accordance with a fifth exemplary embodiment of the present invention.

FIGS. 18 and 19 are cross-sectional views showing the structure of a light-emitting diode in accordance with a sixth exemplary embodiment of the present invention.

### MODE FOR INVENTION

While the invention is susceptible to various modifications and alternative forms, specific embodiments thereof are shown by way of example in the drawings and will herein be described in detail. It should be understood, however, that there is no intent to limit the invention to the particular forms disclosed, but on the contrary, the invention is to cover all modifications, equivalents, and alternatives falling within the spirit and scope of the invention. Like numbers refer to like elements throughout the description of the figures.

It will be understood that, although the terms first, second, A, B etc. may be used herein to describe various elements, these elements should not be limited by these terms. These terms are only used to distinguish one element from another. For example, a first element could be termed a second element, and similarly, a second element could be termed a first element, without departing from the scope of the present invention. As used herein, the term “and/or” includes any and all combinations of one or more of the associated listed items.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises”, “comprising”, “includes” and/or “including”, when used herein, specify the presence of stated features, integers, steps, operations, elements, and/or components, but do not preclude the presence or addition of one or more other features, integers, steps, operations, elements, components, and/or groups thereof.

Unless otherwise defined, all terms, including technical and scientific terms, used herein have the same meaning as commonly understood by one of ordinary skill in the art to which this invention pertains. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, exemplary embodiments of the present invention will be described in detail with reference to the accompanying drawings. Like reference numerals in the drawings denote like elements, and thus repeated descriptions will be omitted.

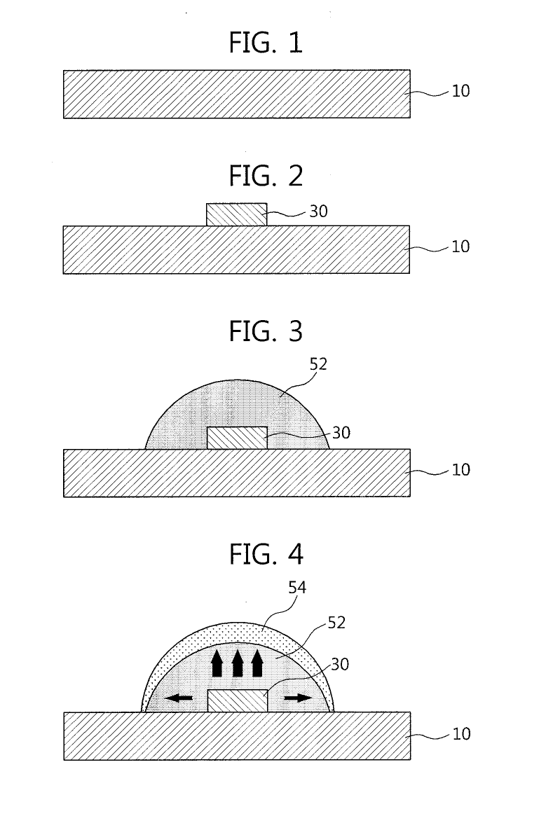

FIGS. 1 to 5 are cross-sectional views showing a method for fabricating a light-emitting diode in accordance with a first exemplary embodiment of the present invention, in which the light-emitting diode is limited to a unit cell.

Referring to FIG. 1, a base structure 10 is provided. The base structure 10 may be a package frame or a base substrate. When the base structure 10 is a package frame, the package frame may comprise the base substrate. The base substrate may be a sub-mount substrate or a light-emitting diode wafer. The light-emitting diode wafer is in a state before being separated in units of light-emitting diode chips and represents the state where the light-emitting diodes are formed on the wafer. The base substrate may be a silicon substrate, a metal substrate, a ceramic substrate, or a resin substrate.

The base structure 10 may be a package lead frame or a package pre-mold frame. The base structure 10 may comprise bonding pads (not shown). The bonding pads may contain Au, Ag, Cr, Ni, Cu, Zn, Ti, Pd, etc. An external connection terminal (not shown) connected to each of the bonding pads may be disposed on the outside of the base structure 10. The bonding pads and the external connection terminals may be provided in the package lead frame.

Referring to FIG. 2, a light-emitting diode chip 30 is disposed on the base structure 10. Here, when the base structure 10 is a light-emitting diode wafer, the step of disposing the light-emitting diode may be omitted.

The light-emitting diode chip 30 comprises a first clad layer, a second clad layer, and an active layer interposed therebetween. The first clad layer may be a semiconductor layer doped with a first type impurity, e.g., an n-type impurity. The first clad layer may be a nitride semiconductor, a gallium arsenide semiconductor layer, or a zinc oxide semiconductor layer doped with an impurity such as Si, N, B, P, etc.

The second clad layer may be a semiconductor layer doped with a second type impurity, e.g., a p-type impurity. The second clad layer may be a nitride semiconductor, a gallium arsenide semiconductor layer, or a zinc oxide semiconductor layer doped with a p-type impurity such as Mg, N, P, As, Zn, Li, Na, K, Cu, etc.

The active layer may have a single-quantum dot structure or a multi-quantum well structure. When the active layer is a nitride layer, the nitride layer may be an InGaN layer and/or a GaN layer. When the active layer is a zinc oxide layer, the zinc oxide layer may be a ZnMgO layer or a ZnCdO layer.

The light-emitting diode chip 30 emits light by recombination of electrons and holes when an electric field is applied between the first clad layer and the second clad layer. The light-emitting diode chip 30 may be selected from the group consisting of an AlGaAs light-emitting diode chip, an InGaAs light-emitting diode chip, an AlGaInP light-emitting diode chip, an AlGaInPAs light-emitting diode chip, a GaN light-emitting diode chip, and a ZnO light-emitting diode chip. Moreover, the light-emitting diode chip 30 may be a device that emits blue light or ultraviolet light.

The light-emitting diode chip 30 may be a horizontal light-emitting diode chip including both an n electrode and a p electrode formed on the upper surface thereof. The n electrode and the p electrode may be electrically connected to the bonding pads through wires, respectively. However, the present invention is not limited thereto, and the light-emitting diode chip 30 may be flipped over and surface-mounted to the bonding pads using conductive balls(not shown).

Referring to FIG. 3, a first protective layer 52 having a dome shape may be formed on the light-emitting diode chip 30. The first protective layer 52 may serve as a protective film and also serve to encapsulate the light-emitting diode chip 30. The first protective layer 52 may be a transparent material layer. In detail, the first protective layer 52 may comprise one selected from the group consisting of glass and resin. The resin may be selected from the group consisting of silicone resin, epoxy resin, acrylic resin, urethane resin, photoresist, and equivalents thereof.

The first protective layer 52 may be formed by any method such as compression molding, transfer molding, dotting, blade coating, screen coating, dip coating, spin coating, spray, inkjet printing, etc. However, the first protective layer may be omitted.

Referring to FIG. 4, a wavelength conversion material layer 54 is formed on the first protective layer 52 such that the area adjacent to the upper surface of the light-emitting diode chip 30 is thicker than the area adjacent to the side of the light-emitting diode chip 30. Preferably, the wavelength conversion material layer 54 has a thickness profile proportional to the amount of light emitted from the light-emitting diode chip 30. Meanwhile, when the first protective layer 52 is omitted, the wavelength conversion material layer 54 is formed on the light-emitting diode chip 30.

The wavelength conversion material layer 54 may comprise a wavelength conversion material and a light-transmitting photocurable material. Thus, the light emitted from the light-emitting diode chip 30 can be converted into light having a longer wavelength, thereby implementing a white light-emitting diode.

The wavelength conversion material may be selected from the group consisting of a fluorescent material, a dye, a pigment, and equivalents thereof. The wavelength conversion material may be within one wavelength range selected from the group consisting of yellow, red, green, and blue.

For example, when the light-emitting diode chip 30 is a device that emits blue light, a yellow wavelength conversion material may be contained in the wavelength conversion material layer 54 to implement a white light-emitting diode. When the light-emitting diode chip 30 is a device that emits ultraviolet light, a yellow wavelength conversion material, a red wavelength conversion material, a green wavelength conversion material, and a blue wavelength conversion material may be contained in the wavelength conversion material layer 54 to implement a white light-emitting diode.

In detail, the yellow wavelength conversion material may be an yttrium aluminum garnet (YAG) fluorescent material, a silicate fluorescent material, or a pigment such as lead chromate (PbCrO₄), zinc chromate (ZnCrO₄), cadmium sulfide/zinc sulfide (CdS-ZnS), etc. In detail, the YAG fluorescent material may be YAG:Ce, TbYAG:Ce, GdYAG:Ce, or GdTbYAG:Ce, and the silicate fluorescent material may be methyl silicate, ethyl silicate, magnesium aluminum silicate, or aluminum silicate.

The red wavelength conversion material may be a sulfide fluorescent material, a nitride fluorescent material, or a pigment such as iron oxide (Fe₂O₃), lead tetraoxide (Pb₃O₄), mercury sulfide (HgS), etc. In detail, the sulfide fluorescent material may be SrS:Eu or CaS:Eu, and the nitride fluorescent material may be SrSiN:Eu, CaSiN:Eu, CaAlSiN, (Ca,Sr,Ba)SiN:Eu, LaSiN:Eu, or Sr-α-SiAlON.

The green wavelength conversion material may be a fluorescent material such as BaSiO:Eu, SrSiO:Eu, SrAlO:Eu, SrAlO:Eu, SrGaS:Eu, SrSiAlON:Eu, (Ca,Sr,Ba)SiNO:Eu, YSiON:Tb, YSiON:Tb, GdSiON:Tn, etc. or a pigment such as chromium oxide (Cr₂O₃), chromium hydroxide (Cr₂O(OH)₄), basic copper acetate (Cu(C₂H₃O2)—2Cu(OH)₂), cobalt green (Cr₂O₃—Al₂O₃—CoO), etc.

The blue wavelength conversion material may be a fluorescent material such as Sr(PO)Cl:Eu, SrMgSiO:Eu, BaMgSiO:Eu, BaMgAlO:Eu, SrPO:Eu, SrSiAlON:Eu, etc. or a pigment such as Prussian blue (Fe₄[Fe(CN)₆]₃), cobalt blue (CoO—Al₂O₃), etc.

The light-transmitting photocurable material may be a light-transmitting polymer or an inorganic material, which is cured by light. For example, the light-transmitting photocurable material may comprise one selected from the group consisting of silicone resin, epoxy resin, acrylic resin, urethane resin, photoresist, glass, and equivalents thereof.

The wavelength conversion material layer 54 may be formed by the following steps. First, a mixture containing a wavelength conversion material and a light-transmitting photocurable material may be coated on the first protective layer 52. Here, when the first protective layer 52 is omitted, the mixture containing the wavelength conversion material and the light-transmitting photocurable material is coated on the light-emitting diode chip 30.

The mixture may be coated by any method such as blade coating, screen coating, dip coating, dotting, spin coating, spray, inkjet printing, etc.

The light-transmitting photocurable material may be cured by exposing the mixture containing the wavelength conversion material and the light-transmitting photocurable material to light emitted by applying an electric field to the light-emitting diode chip 30. Here, the light-transmitting photocurable material may be cured to a thickness proportional to the amount of light emitted from the light-emitting diode chip 30.

In other words, the light-emitting diode chip 30 emits a large amount of light from the upper surface, and the amount of light emitted from the side of the light-emitting diode chip 30 is reduced compared to that emitted from the upper surface. Accordingly, the mixture located on the upper surface of the light-emitting diode chip 30 may be more cured than the mixture located on the side of the light-emitting diode chip 30. As a result, the wavelength conversion material layer 54 adjacent to the upper surface of the light-emitting diode chip 30 may be thicker than the wavelength conversion material layer 54 adjacent to the side of the light-emitting diode chip 30.

Thereafter, the light-emitting diode chip 30 is isolated from the mixture, and the residual uncured mixture may be removed by development or washing.

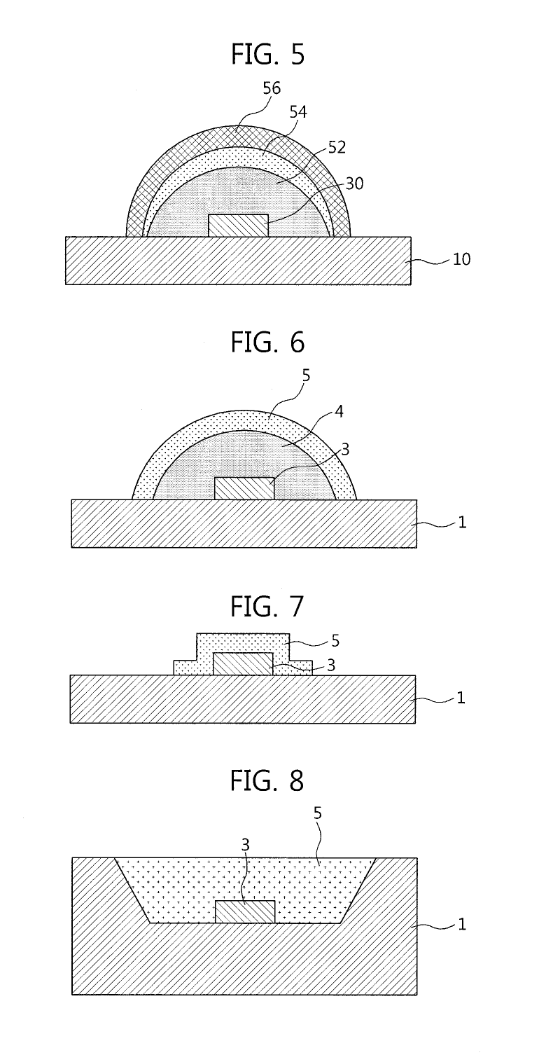

Referring to FIG. 5, a second protective layer 56 may be formed on the wavelength conversion material layer 54. The second protective layer 56 may comprise glass or light-transmitting resin. The light-transmitting resin may be general resin, such as silicone resin, epoxy resin, acrylic resin, urethane resin, etc, or photoresist. However, the second protective layer 56 may be omitted.

Although the light-emitting diode is limited to a unit cell in the exemplary embodiment of the present invention, when the base structure 10 is a sub-mount substrate or a light-emitting diode wafer, a plurality of light-emitting diode chips 30, each including the wavelength conversion material layer 54, are formed on the sub-mount substrate or the light-emitting diode wafer, and then the sub-mount substrate or the light-emitting diode wafer may be cut into a plurality of unit cells.

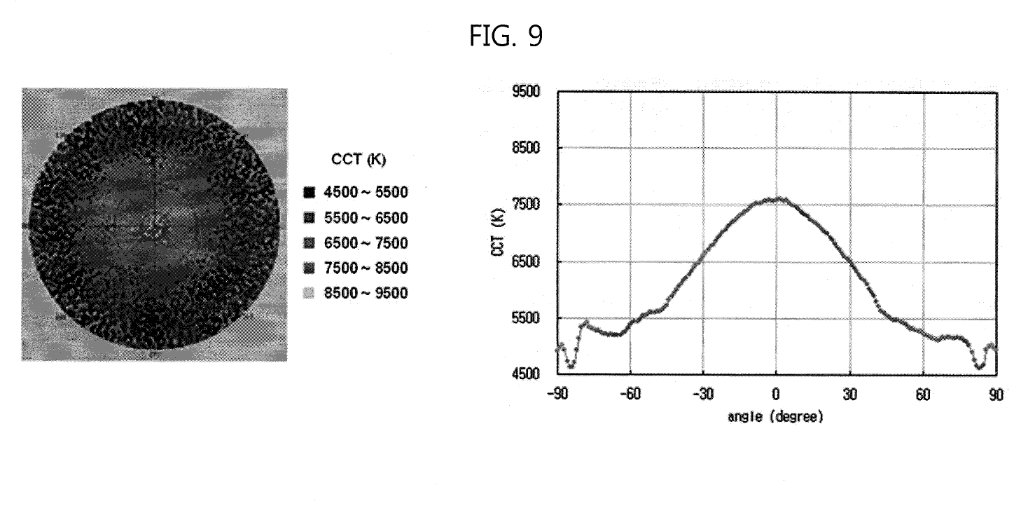

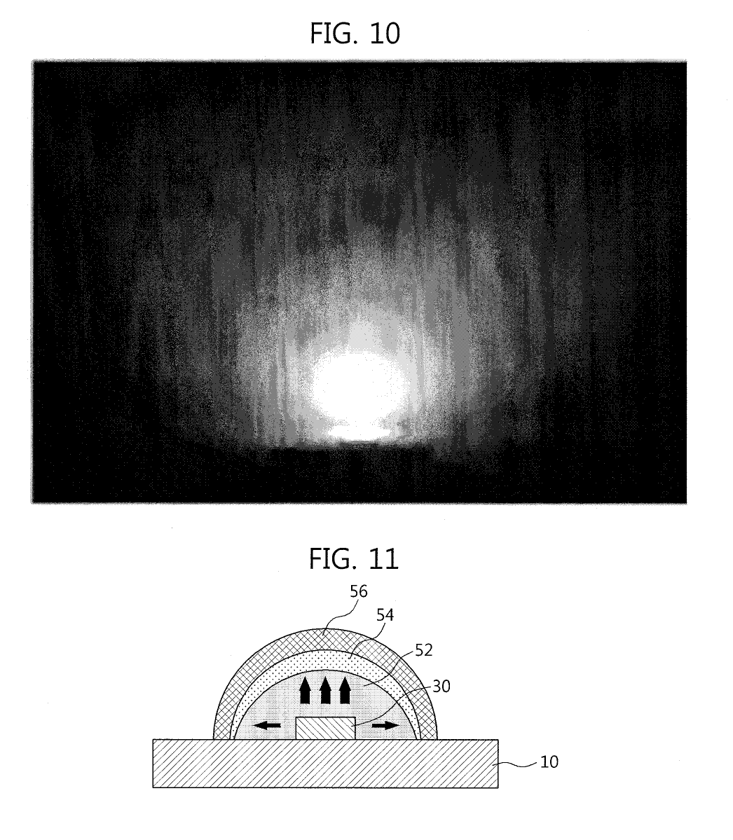

FIGS. 6 to 8 are cross-sectional views showing various structures of conventional light-emitting diodes, and FIGS. 9 and 10 are an image and a graph showing color temperature distribution of a conventional light-emitting diode.

Referring to FIGS. 6 and 10, according to a conventional light-emitting diode, a light-emitting diode chip 3 may be disposed on a substrate 1, and a wavelength conversion material layer 5 may be disposed on the light-emitting diode chip 3. The wavelength conversion material layer 5 is a layer that does not contain a light-transmitting photocurable material, unlike the light-emitting diode according to the present invention.

When an electric field is applied to the light-emitting diode chips 3 of FIGS. 6 to 8, light may be emitted from the light-emitting diode chip 3. This light excites a wavelength conversion material contained in the wavelength conversion material layer 5 to emit light and this light is mixed with the light from the light-emitting diode, thereby emitting white light. Here, the amount of light emitted from the upper surface of the light-emitting diode chip 3 is more predominant than that emitted from the side of the light from the light-emitting diode chip 3.

However, when the wavelength conversion material layer 5 whose thickness is not controlled for each light orientation angle is provided in the conventional light-emitting diode, the amount of wavelength conversion material formed on the upper surface of the light-emitting diode chip 3 may be smaller than the ability of light to excite the wavelength conversion material, and the amount of light for exciting the wavelength conversion material may be insufficient in the side of the light-emitting diode chip 3. Accordingly, the color of light source may be predominant in the center of light finally emitted, and the color of the wavelength conversion material may be predominant in the side of light. As a result, the light emitted from the light-emitting diode may have non-uniform color temperature distribution for each orientation angle.

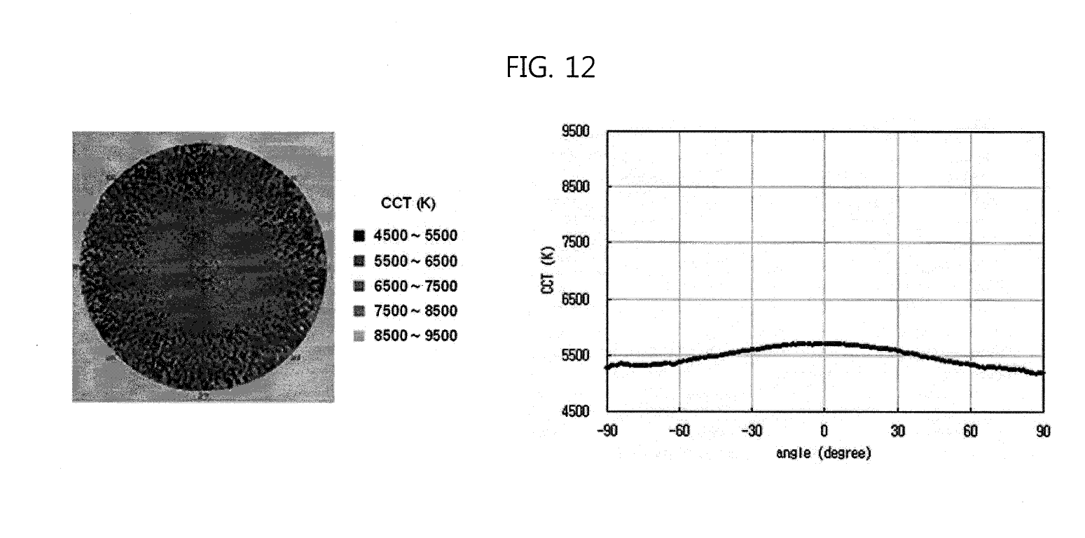

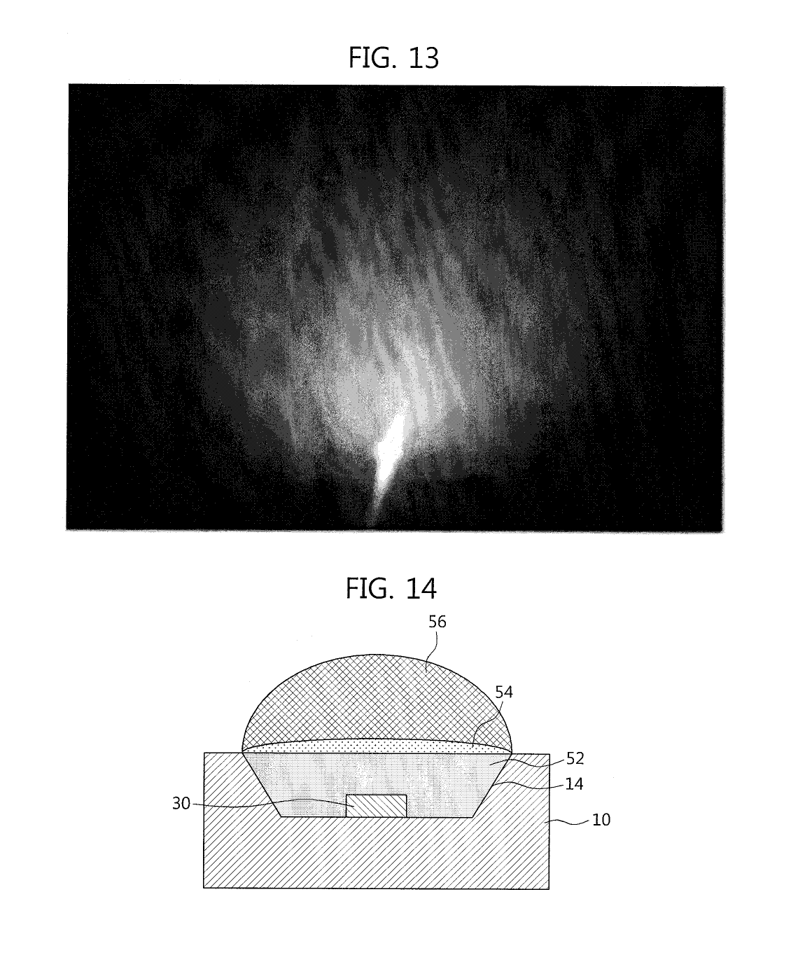

FIG. 11 is a cross-sectional view showing the structure of a light-emitting diode in accordance with the present invention, and FIGS. 12 and 13 are an image and a graph showing color temperature distribution of a light-emitting diode in accordance with the present invention.

Referring to FIGS. 11 to 13, the light-emitting diode according to the present invention comprises a wavelength conversion material layer 54 containing the wavelength conversion material formed over the area, into which light emitted from the light-emitting diode chip 30 can penetrate, and thus the light emitted from the light-emitting diode chip 30 can excite the wavelength conversion material to a certain level.

As a result, since the wavelength conversion material layer 54 proportional to the amount of emitted light or the intensity of emitted light passes through the path of light emitted from the light-emitting area of the light-emitting diode, the amount of light energy emitted from the wavelength conversion material and the amount of light energy emitted from the light-emitting diode are mixed in an appropriate ratio, and thus the color temperature distribution for each orientation angle can be uniform.

Next, the structures of light-emitting diodes in accordance with other exemplary embodiment of the present invention will be described, which are fabricated by the same method described above with reference to FIGS. 1 to 5, except for those described as follows.

FIG. 14 is a cross-sectional view showing the structure of a light-emitting diode in accordance with a second exemplary embodiment of the present invention.

Referring to FIG. 14, according a light-emitting diode in accordance with a second exemplary embodiment of the present invention, a base structure 10 may include a reflective cup 14. That is, the base structure 10 may be a package frame including a reflective cup or a base substrate including a reflective cup. In detail, the base structure 10 may be a pre-mold lead frame including a reflective cup or a sub-mount substrate including a reflective cup.

As a result, the light-emitting diode may comprise the base structure 10 including the reflective cup 14, a light-emitting diode chip 30 disposed in the reflective cup 14, a first protective layer 52 disposed on the light-emitting diode chip 30, a wavelength conversion material layer 54 disposed on the first protective layer 52 such that the area adjacent to the upper surface of the light-emitting diode chip 30 is thicker than the area adjacent to the side of the light-emitting diode chip 30, and a second protective layer 56 disposed on the wavelength conversion material layer 54. Here, it is preferred that the wavelength conversion material layer 54 has a thickness profile proportional to the amount of light emitted from the light-emitting diode chip 30.

With the reflective cup 14 provided in the base structure 10, it is possible to reduce the amount of light absorbed and scattered by the base structure 10, thereby improving the light-emitting efficiency. The first protective layer 52 may be omitted.

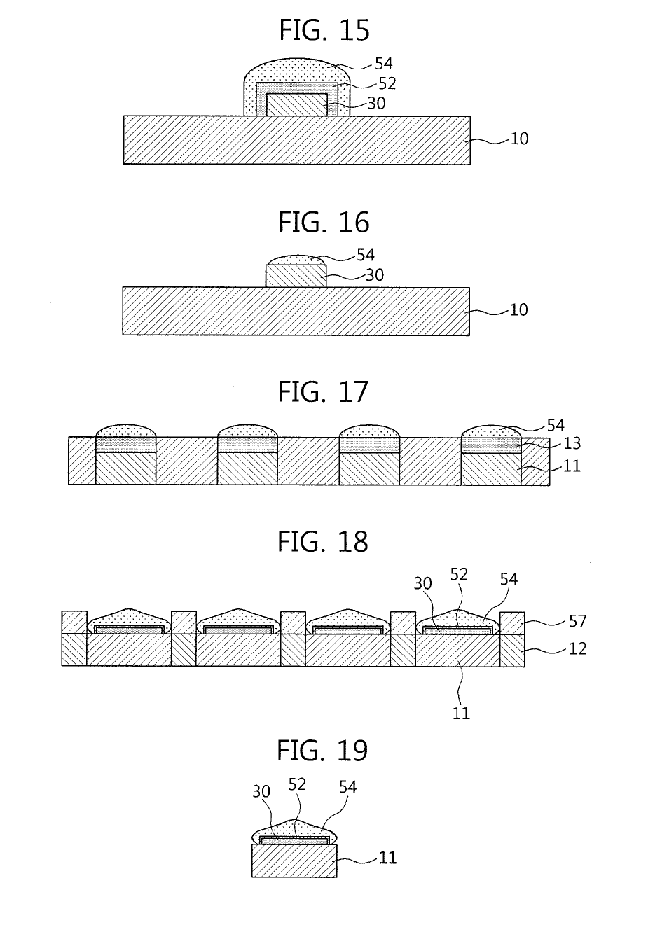

FIG. 15 is a cross-sectional view showing the structure of a light-emitting diode in accordance with a third exemplary embodiment of the present invention.

Referring to FIG. 15, a light-emitting diode in accordance with a third exemplary embodiment of the present invention may comprise a light-emitting diode chip 30 located on a base structure 10, a protective layer 52 conformally formed with a uniform thickness on the light-emitting diode 30, and a wavelength conversion material layer 54 formed on the protective layer 52 such that the area adjacent to the upper surface of the light-emitting diode chip 30 is thicker than the area adjacent to the side of the light-emitting diode chip 30. The base structure 10 may be a sub-mount substrate.

When the protective layer 52 is conformally formed on the light-emitting diode chip 30, the volume of the finally fabricated light-emitting diode can be reduced compared to a the protective layer 52 formed into a dome shape, and thus the protective layer 52 can be easily applied to a small light-emitting diode.

FIG. 16 is a cross-sectional view showing the structure of a light-emitting diode in accordance with a fourth exemplary embodiment of the present invention.

Referring to FIG. 16, a light-emitting diode in accordance with a forth exemplary embodiment of the present invention may comprise a vertical light-emitting diode chip 30 located on a base structure 10 and a wavelength conversion material layer 54 formed on the vertical light-emitting diode chip 30 such that the area adjacent to the center of a light-emitting area of the light-emitting diode chip 30 is thicker than the area adjacent to the side of the light-emitting area of the light-emitting diode chip 30. The light-emitting diode has a structure in which the vertical light-emitting diode chip 30 is applied to the light-emitting diode of FIG. 15 and the protective layer 52 is omitted.

Moreover, in the case of the vertical light-emitting diode chip, the amount of light emitted from the side of the light-emitting diode chip is small, and thus the wavelength conversion material layer 54 may not be disposed on the side of the light-emitting diode. As a result, it is possible to reduce the fabrication cost.

FIG. 17 is a cross-sectional view showing the structure of a light-emitting diode in accordance with a fifth exemplary embodiment of the present invention.

Referring to FIG. 17, a light-emitting diode in accordance with a fifth exemplary embodiment of the present invention may comprise a light emitting diode wafer 11 in which a plurality of light-emitting areas 13 are provided. The light emitting diode wafer 11 represents a state in which a plurality of light-emitting diode chips are not separated into a plurality of unit cells, and each of the light-emitting areas 13 may have the structure of the vertical light-emitting diode.

Wavelength conversion materials 54 having a dome shape, in which the area adjacent to the center of the light-emitting area 13 is thicker than the area adjacent to the side of the light-emitting area 13, are disposed on the light-emitting diode wafer 11.

After disposing the wavelength conversion materials 54, the light-emitting diode wafer 11 may be cut into a plurality of unit cells.

According to the above-described light-emitting diode in accordance with the fifth exemplary embodiment of the present invention, the wavelength conversion material layer 54 containing the light-transmitting photocurable material can be formed on the light-emitting diode wafer 11, and thus it is possible to simplify the fabrication process and reduce the fabrication time.

FIGS. 18 and 19 are cross-sectional views showing the structure of a light-emitting diode in accordance with a sixth exemplary embodiment of the present invention.

Referring to FIGS. 18 and 19, according to a light-emitting diode in accordance with a sixth exemplary embodiment of the present invention, a plurality of light-emitting diode chips 30 are formed on a light-emitting diode wafer 11, which are divided into a plurality of cell areas by a plurality of cutting lines 12 and a separation pattern 57. Here, the separation pattern 57 may formed of a general photoresist material.

Then, a protective layer 52 for encapsulating each light-emitting diode chip 30 is formed on the light-emitting diode wafer 11 on which the light-emitting diodes 30 are formed, and a mixture containing a wavelength conversion material and a light-transmitting photocurable material is coated on the protective layer 52.

Thereafter, the mixture containing the wavelength conversion material and the light-transmitting photocurable material may be cured by exposing the mixture to light emitted by applying an electric field to the light-emitting diode chips 30. Here, the cured area of the mixture has a thickness profile proportional to the amount of light emitted from the light-emitting diode chips 30.

After curing the mixture, the residual mixture containing the wavelength conversion material and the uncured light-transmitting photocurable material may be removed by development or washing, thereby forming the wavelength conversion material layer 54. As a result, the wavelength conversion material layer 54 has a thickness profile proportional to the amount of light emitted from the light-emitting diode chips 30.

Moreover, when the residual mixture containing the wavelength conversion material and the light-transmitting photocurable material is removed by development, the separation pattern 57 can be removed at the same time.

Thereafter, the light-emitting diode wafer 11 may be cut into a plurality of light-emitting diode cells by performing a cutting process using the cutting lines 12.

1. A light-emitting diode comprising:
a base structure;
a light-emitting diode chip disposed on the base structure; and
a wavelength conversion material layer formed on the light-emitting diode chip such that the area adjacent to the upper surface of the light-emitting diode chip is thicker than the area adjacent to the side of the light-emitting diode chip.

2. The light-emitting diode of claim 1, wherein the wavelength conversion material layer has a thickness profile proportional to the amount of light emitted from the light-emitting diode chip.

3. The light-emitting diode of claim 2, wherein the wavelength conversion material layer comprises a light-transmitting photocurable material and a wavelength conversion material.

4. The light-emitting diode of claim 3, wherein the light-transmitting photocurable material comprises one selected from the group consisting of silicone resin, epoxy resin, acrylic resin, urethane resin, photoresist, and glass.

5. The light-emitting diode of claim 3, wherein the wavelength conversion material has at least one wavelength range selected from the group consisting of yellow, red, green, and blue.

6. The light-emitting diode of claim 3, wherein the wavelength conversion material comprises at least one selected from the group consisting of a fluorescent material, a dye, and a pigment.

7. The light-emitting diode of claim 1, wherein the base structure is selected from the group consisting of a package lead frame, a package pre-mold frame, a sub-mount substrate, and a light-emitting diode wafer.

8. The light-emitting diode of claim 7, wherein the light-emitting diode chip is a vertical light-emitting diode chip and is disposed in or on the light-emitting diode wafer.

9. The light-emitting diode of claim 1, wherein the base structure comprises a reflective cup.

10. The light-emitting diode of claim 1, further comprising a protective layer disposed between the light-emitting diode chip and the wavelength conversion material layer, wherein the protective layer encapsulates the light-emitting diode chip.

11. The light-emitting diode of claim 10, wherein the protective layer has a dome shape that covers the light-emitting diode chip or a conformal shape that covers the light-emitting diode chip and has a uniform thickness.

12. The light-emitting diode of claim 10, wherein the protective layer comprises one selected from the group consisting of glass and light-transmitting resin.

13. The light-emitting diode of claim 1, wherein the light-emitting diode chip is a device that emits light selected from the group consisting of blue light and ultraviolet light.

14. The light-emitting diode of claim 1, further comprising a protective layer disposed on the wavelength conversion material layer.

15. The light-emitting diode of claim 14, wherein the protective layer comprises one selected from the group consisting of glass and light-transmitting resin.

16. A method for fabricating a light-emitting diode, the method comprising the steps of:
disposing a light-emitting diode chip on a base structure; and
forming a wavelength conversion material layer on the light-emitting diode chip,
wherein the wavelength conversion material layer comprises a light-transmitting photocurable material,
wherein the wavelength conversion material layer is formed such that the area adjacent to the upper surface of the light-emitting diode chip is thicker than the area adjacent to the side of the light-emitting diode chip.

17. The method of claim 16, wherein the step of forming the wavelength conversion material layer comprises the steps of:
coating a mixture containing a wavelength conversion material and a light-transmitting photocurable material on the light-emitting diode chip;
curing the mixture by exposing the mixture to light emitted by applying an electric field to the light-emitting diode chip; and
removing the residual uncured mixture.

18. The method of claim 17, wherein the mixture is coated by blade coating, screen coating, dip coating, dotting, spin coating, spray, or inkjet printing.

19. The method of claim 16, further comprising the step of forming a protective layer between the base structure and the wavelength conversion material layer.

20. A method for fabricating a light-emitting diode, the method comprising the steps of:
forming a plurality of light-emitting diode chips on a light-emitting diode wafer divided into a plurality of cell areas;
coating a mixture containing a wavelength conversion material and a light-transmitting photocurable material on the light-emitting diode chips;
curing the mixture by exposing the mixture to light emitted by applying an electric field to the light-emitting diode chips;
forming a wavelength conversion material layer by removing the residual uncured mixture; and
cutting the light-emitting diode wafer into a plurality of light-emitting diode cells.

21. The method of claim 20, wherein the cell areas of the light-emitting diode wafer are defined by a plurality of cutting lines and a separation pattern.

22. The method of claim 21, wherein the residual uncured mixture is removed by development and the separation pattern is also removed by development.

23. The method of claim 21, further comprising the step of, before the step of coating the mixture containing a wavelength conversion material and a light-transmitting photocurable material, forming a protective layer for encapsulating the light-emitting diode chips.
